(19) United States
(12) Patent Application Publication
(10) Pub. No.: US 2013/0233386 A1
(43) Pub. Date: Sep. 12, 2013

(54) GLASS SUBSTRATE FOR CU-IN-GA-SE SOLAR CELLS AND SOLAR CELL USING SAME

(71) Applicant: ASAHI GLASS COMPANY, LIMITED, Chiyoda-ku (JP)

(72) Inventors: Yu HANAWA, Tokyo (JP); Yutaka KUROIWA, Tokyo (JP); Tetsuya NAKASHIMA, Tokyo (JP); Reo USUI, Tokyo (JP)

(73) Assignee: ASAHI GLASS COMPANY, LIMITED, Chiyoda-ku (JP)

(21) Appl. No.: 13/867,490

(22) Filed: Apr. 22, 2013

Related U.S. Application Data
(63) Continuation of application No. PCT/JP2011/074049, filed on Oct. 19, 2011.

(30) Foreign Application Priority Data
Oct. 20, 2010 (JP) 2010-235349

(51) Int. Cl. H01L 31/02; H01L 31/0272

(52) U.S. Cl. CPC H01L 31/02; H01L 31/0272
USPC 136/262; 501/70; 501/67

(57) ABSTRACT

A glass substrate for a Cu—In—Ga—Se solar cell. The glass substrate contains specific oxides with the specific amounts, respectively. The glass substrate has a glass transition temperature of from 650 to 750° C., an average coefficient of thermal expansion within a range of from 50 to 350° C. of from 75×10⁻⁷ to 95×10⁻⁷/° C., a relationship between a temperature (T₄), at which a viscosity reaches 10⁴ dPa·s, and a devitrification temperature (T_{L}) of T₄−T_{L}≧−30° C., a density of 2.6 g/cm³ or less, and a brittleness index of less than 7,000 m^{-1/2}.

### DESCRIPTION

1. Technical Field

The present invention relates to a glass substrate for a solar cell including a photoelectric conversion layer formed between glass substrates. More specifically, the present invention typically relates to: a glass substrate for a Cu—In—Ga—Se solar cell including a glass substrate and a cover glass, in which a photoelectric conversion layer including, as a main component, an element of the Group 11, Group 13 or Group 16 is formed between the glass substrate and the cover glass; and a solar cell using the same.

2. Background Art

Group 11-13 and Group 11-16 compound semiconductors having a chalcopyrite structure and Group 12-16 compound semiconductors of a cubic system or hexagonal system have a large absorption coefficient to light in the visible to near-infrared wavelength range. Thus, they are expected as a material for high-efficiency thin film solar cell. Representative examples thereof include Cu(In,Ga)Se₂ (hereinafter referred to as “CIGS” or “Cu—In—Ga—Se”) and CdTe.

In the CIGS thin film solar cell, in view of the matters that it is inexpensive and that its average coefficient of thermal expansion is close to that of the CIGS compound semiconductor, a soda lime glass is used as a substrate, and a solar cell is obtained.

Also, in order to obtain a solar cell with good efficiency, a glass material which withstands a heat treatment temperature of high temperatures has been proposed (see Patent Documents 1 and 2).

3. Prior Art Documents

### Patent Document

Patent Document 1: JP-A-11-135819

Patent Document 2: JP-A-2011-9287

### SUMMARY OF THE INVENTION

### Problems to be Solved by the Invention

A CIGS photoelectric conversion layer (hereinafter referred to as “CIGS layer”) is formed on the glass substrate. As disclosed in Patent Documents 1 and 2, in order to fabricate a solar cell with good cell efficiency, a heat treatment at a higher temperature is preferable, and the glass substrate is required to withstand it. In Patent Document 1, a glass composition having a relatively high annealing point has been proposed; however, it is not always said that the invention described in Patent Document 1 has high cell efficiency.

Moreover, it is an object of the process of Patent Document 2 to efficiently diffuse alkali elements with a low concentration which are contained in a high strain point glass into a p-type light absorbing layer by providing an alkali controlling layer. However, a cost is required for a step of providing the alkali controlling layer which should be added, and the diffusion of the alkali elements becomes insufficient due to the alkali controlling layer, so that there is a concern that efficiency decreases.

The present inventors discovered that the cell efficiency could be enhanced by increasing an alkali in a glass substrate in a prescribed range; however, there was a problem that the increase of the amount of alkali brought a lowering of a glass transition temperature (Tg) thereof

On the other hand, for the purpose of preventing peeling of the CIGS layer on the glass substrate during and after deposition, the glass substrate is required to have a predetermined average coefficient of thermal expansion.

Furthermore, from the viewpoint of fabrication and use of the CIGS solar cell, strength improvement and weight saving of the glass substrate and no devitrification upon sheet glass forming are required.

Thus, for a glass substrate to be used in a CIGS solar cell, it is difficult to have properties of high cell efficiency, high glass transition temperature, a predetermined average coefficient of thermal expansion, high glass strength, low glass density, and prevention of devitrification upon sheet glass forming with good balance.

An object of the present invention is to provide a glass substrate for a Cu—In—Ga—Se solar cell having properties of high cell efficiency, high glass transition temperature, a predetermined average coefficient of thermal expansion, high glass strength, low glass density, and prevention of devitrification upon sheet glass forming with good balance.

### Means for Solving the Problems

The present invention provides the following glass substrate for a Cu—In—Ga—Se solar cell and solar cell.

(1) A glass substrate for a Cu—In—Ga—Se solar cell, containing, in terms of mol % on the basis of the following oxides,

from 55 to 70% of SiO₂,

from 6.5 to 12.6% of Al₂O₃,

from 0 to 1% of B₂O₃,

from 3 to 10% of MgO,

from 0 to 4.8% of CaO,

from 0 to 2% of SrO,

from 0 to 2% of BaO,

from 0 to 2.5% of ZrO₂,

from 0 to 2.5% of TiO₂,

from 5.3 to 10.9% of Na₂O, and

from 0 to 10% of K₂O,

wherein MgO+CaO+SrO+BaO is from 7.7 to 17%,

Na₂O+K₂O is from 10.4 to 16%,

MgO/Al₂O₃ is 0.9 or less,

(2Na₂O+K₂O+SrO+BaO)/(Al₂O₃+ZrO₂) is 2.2 or less,

(Na₂O+K₂O)/Al₂O₃×(Na₂O/K₂O) is 0.9 or more, and

the glass substrate has a glass transition temperature of from 650 to 750° C., an average coefficient of thermal expansion within a range of from 50 to 350° C. of from 75×10⁻⁷ to 95×10⁻⁷/° C., a relationship between a temperature (T₄), at which a viscosity reaches 10⁴ dPa·s, and a devitrification temperature (T_{L}) of T₄−T_{L}≧−30° C., a density of 2.6 g/cm³ or less, and a brittleness index of less than 7,000 m^{-1/2}.

(2) The glass substrate for a Cu—In—Ga—Se solar cell according to (1), which contains, in terms of mol % on the basis of the following oxides,

from 58 to 69% of SiO₂,

from 7 to 12% of Al₂O₃,

from 0 to 0.5% of B₂O₃,

from 4 to 9% of MgO,

from 0 to 4.5% of CaO,

from 0 to 1.5% of SrO,

from 0 to 1.5% of BaO,

from 0 to 1.5% of ZrO₂,

from 0 to 1.5% of TiO₂,

from 6.5 to 10.5% of Na₂O, and

from 2 to 8% of K₂O,

wherein MgO+CaO+SrO+BaO is from 9 to 15%,

Na₂O+K₂O is from 10.5 to 15%,

MgO/Al₂O₃ is from 0.2 to 0.85,

(2Na₂O+K₂O+SrO+BaO)/(Al₂O₃+ZrO₂) is from 1 to 2.2,

(Na₂O+K₂O)/Al₂O₃×(Na₂O/K₂O) is from 0.9 to 10, and

the glass substrate has the glass transition temperature of from 650 to 700° C., the average coefficient of thermal expansion within a range of from 50 to 350° C. of from 75×10⁻⁷ to 90×10⁻⁷/° C., the relationship between a temperature (T₄), at which a viscosity reaches 10⁴ dPa·s, and a devitrification temperature (T_{L}) of T₄−T_{L}≧−20° C., the density of 2.58 g/cm³ or less, and the brittleness index of less than 6,800 m^{-1/2}.

(3) A solar cell, comprising a glass substrate, a cover glass, and a photoelectric conversion layer of Cu—In—Ga—Se formed between the glass substrate and the cover glass, wherein at least the glass substrate of the glass substrate and the cover glass is the glass substrate for a Cu—In—Ga—Se solar cell according to (1) or (2).

### Advantage of the Invention

The glass substrate for a Cu—In—Ga—Se solar cell of the present invention can have properties of high cell efficiency, high glass transition temperature, a predetermined average coefficient of thermal expansion, high glass strength, low glass density, and prevention of devitrification upon sheet glass forming with good balance. Also, a solar cell exhibiting high cell efficiency can be provided by using the glass substrate for a CIGS solar cell of the present invention.

The present application relates to the subject of Japanese Patent Application No. 2010-235349 filed on Oct. 20, 2010, and the disclosed contents thereof are incorporated herein by reference.

### BRIEF DESCRIPTION OF THE DRAWINGS

FIG. 1 is a cross-sectional view schematically showing an example of embodiments of a solar cell using the glass substrate for a CIGS solar cell of the present invention.

FIG. 2 shows (a) a solar cell prepared on a glass substrate for evaluation in Examples and (b) a cross-sectional view thereof.

FIG. 3 shows a CIGS solar cell for evaluaion on a glass substrate for evaluation, where eight pieces of the solar cell shown in FIG. 2 are arranged.

FIG. 4 shows a graph illustrating a relationship between (Na₂O+K₂O)/Al₂O₃×(Na₂O/K₂O) and cell efficiency.

### MODE FOR CARRYING OUT THE INVENTION

The glass substrate for a Cu—In—Ga—Se solar cell of the present invention is described hereinbelow.

The glass substrate for a Cu—In—Ga—Se solar cell of the present invention contains, in terms of mol % on the basis of the following oxides,

from 55 to 70% of SiO₂,

from 6.5 to 12.6% of Al₂O₃,

from 0 to 1% of B₂O₃,

from 3 to 10% of MgO,

from 0 to 4.8% of CaO,

from 0 to 2% of SrO,

from 0 to 2% of BaO,

from 0 to 2.5% of ZrO₂,

from 0 to 2.5% of TiO₂,

from 5.3 to 10.9% of Na₂O, and

from 0 to 10% of K₂O,

wherein MgO+CaO+SrO+BaO is from 7.7 to 17%,

Na₂O+K₂O is from 10.4 to 16%,

MgO/Al₂O₃ is 0.9 or less,

(2Na₂O+K₂O+SrO+BaO)/(Al₂O₃+ZrO₂) is 2.2 or less,

(Na₂O+K₂O)/Al₂O₃×(Na₂O/K₂O) is 0.9 or more, and

the glass substrate has a glass transition temperature of from 650 to 750° C., an average coefficient of thermal expansion within a range of from 50 to 350° C. of from 75×10⁻⁷ to 95×10⁻⁷/° C., a relationship between a temperature (T₄), at which a viscosity reaches 10⁴ dPa·s, and a devitrification temperature (T_{L}) of T₄−T_{L}≧−30° C., a density of 2.6 g/cm³ or less, and a brittleness index of less than 7,000 m^{-1/2}.

The glass transition temperature (Tg) of the glass substrate for a CIGS solar cell of the present invention is from 650 to 750° C. The glass transition temperature of the glass substrate for a CIGS solar cell of the present invention is higher than a glass transition temperature of soda lime glass. For the purpose of ensuring the formation of a photoelectric conversion layer at high temperatures, the glass transition temperature (Tg) of the glass substrate for a CIGS solar cell of the present invention is preferably 650° C. or higher. For the purpose of not excessively increasing the viscosity during melting, the glass transition temperature is preferably 750° C. or lower, more preferably 700° C. or lower, and still more preferably 680° C. or lower.

The average coefficient of thermal expansion within the range of from 50 to 350° C. of the glass substrate for a CIGS solar cell of the present invention is from 75×10⁻⁷ to 95×10⁻⁷/° C. When it is less than 75×10⁷/° C. or exceeds 95×10⁻⁷/° C., a difference in thermal expansion between the glass substrate and the CIGS layer is excessively large, so that defects such as peeling are easily caused. It is more preferably 90×10⁻⁷/° C. or less and still more preferably 85×10⁻⁷/° C. or less.

In the glass substrate for a CIGS solar cell of the present invention, a relationship between a temperature (T₄), at which a viscosity reaches 10⁴ dPa·s and a devitrification temperature (T_{L}) is T₄−T₁≧−30° C. When T₄−T_{L} is lower than −30° C., devitrification is prone to occur during the formation of the sheet glass and thus there is a concern that forming of a glass sheet becomes difficult. The relationship of T₄−T_{L} is preferably −20° C. or higher, more preferably −10° C. or higher, still more preferably 0° C. or higher, and especially preferably 10° C. or higher. Here, the devitrification temperature means a maximum temperature at which a crystal is not precipitated on the glass surface and inside the glass when the glass is kept in a specific temperature for 17 hours.

Taking the formability of the glass sheet into consideration, T₄ is preferably 1,300° C. or lower, more preferably 1,270° C. or lower, and still more preferably 1,250° C. or lower.

The glass substrate for a CIGS solar cell of the present invention has a density of 2.6 g/cm³ or less. When the density exceeds 2.6 g/cm³, product weight increases and thus the case is not preferred. The density is preferably 2.58 g/cm³ or less and more preferably 2.57 g/cm³ or less. Moreover, for the purpose of assuring the degree of freedom of the constituting components of the glass, the density is preferably 2.4 g/cm³ or more.

In the glass substrate for a CIGS solar cell of the present invention, a brittleness index is less than 7,000 m^{-1/2}. When the brittleness index is 7,000 m^{-1/2} or more, the glass substrate is prone to be broken in the manufacturing process of the solar cell and thus the case is not preferred. The brittleness index is preferably 6,900 m^{-1/2} or less and more preferably 6,800 m^{-1/2} or less.

In the present invention, the brittleness index of the glass substrate is obtained as “B” defined by the following formula (1) (J. Sehgal, et al., J. Mat. Sci. Lett., 14, 167 (1995)).

c/a=0.0056B^{2/3}P^{1/6} (1)

Here, P is a pressing load of a Vickers indenter and a and c are a diagonal length of the Vickers indentation mark and a length of cracks formed from the four corners (total length of symmetrical two cracks including the mark of the indenter). The brittleness index B is calculated using the size of the Vickers indentation marks formed on various glass substrate surface and the formula (1).

The reasons why the glass substrate for a CIGS solar cell of the present invention is limited to the foregoing composition are as follows.

SiO₂: SiO₂ is a component for forming a network of glass, and when its content is less than 55 mol % (hereinafter referred to simply as “%”), there is a concern that the heat resistance and chemical durability of the glass substrate are lowered, and the average coefficient of thermal expansion within the rage of 50 to 350° C. increases. The content thereof is preferably 58% or more, more preferably 60% or more, and still more preferably 62% or more.

However, when it exceeds 70%, there is a concern that the viscosity at a high temperature of the glass increases, and a problem that the meltability is deteriorated is caused. The content thereof is preferably 69% or less, more preferably 68% or less, and still more preferably 67% or less.

Al₂O₃: Al₂O₃ increases the glass transition temperature, enhances the weather resistance (solarization), heat resistance and chemical durability, and increases a Young's modulus. When its content is less than 6.5%, there is a concern that the glass transition temperature is lowered. Also, there is a concern that the average coefficient of thermal expansion within the range of 50 to 350° C. increases. The content thereof is preferably 7% or more, and more preferably 9% or more.

However, when it exceeds 12.6%, there is a concern that the viscosity at a high temperature of glass increases, and the meltability is deteriorated. Also, there is a concern that the devitrification temperature increases, and the formability is deteriorated. Also, there is a concern that the cell efficiency is lowered. The content thereof is preferably 12.4% or less, more preferably 12.2% or less, and still more preferably 12% or less.

B₂O₃: B₂O₃ may be contained in an amount of up to 1% for the purposes of enhancing the meltability, etc. When its content exceeds 1%, the glass transition temperature decreases, or the average coefficient of thermal expansion within the range of 50 to 350° C. becomes small, and thus is not preferable for a process for forming the CIGS layer. In addition, the devitrification temperature is increased to easily cause the devitrification, resulting in difficulty of forming the glass sheet. The content thereof is preferably 0.5% or less. It is more preferred that B₂O₃ is not substantially contained.

The expression “is not substantially contained” means that it is not contained except the case where it is contained as unavoidable impurities originated from raw materials or the like, that is, means that it is not intentionally incorporated.

MgO: MgO is contained because it has effects for decreasing the viscosity during melting of glass, and promoting melting. However, when its content is less than 3%, there is a concern that the viscosity at a high temperature of glass increases, and the meltability is deteriorated. Also, there is a concern that the cell efficiency is lowered. The content thereof is preferably 4% or more, more preferably 5% or more, and still more preferably 6.5% or more.

However, when it exceeds 10%, there is a concern that the average coefficient of thermal expansion within the range of 50 to 350° C. increases. Also, there is a concern that the devitrification temperature increases. The content thereof is preferably 9% or less, and more preferably from 8.5% or less.

CaO: CaO can be contained because it has effects for decreasing the viscosity during melting of glass, and promoting melting. The content thereof is preferably 0.5% or more, and more preferably 1% or more. However, when its content exceeds 4.8%, there is a concern that the average coefficient of thermal expansion within the range of 50 to 350° C. of the glass substrate increases. In addition, there is a concern that sodium is hard to move in the glass substrate, and thus, the cell efficiency is lowered. The content thereof is preferably 4.5% or less, and more preferably 4% or less.

SrO: SrO can be contained because it has effects for decreasing the viscosity during melting of glass, and promoting melting. However, when its content exceeds 2% , there is a concern that the cell efficiency is lowered, and the average coefficient of thermal expansion within the range of 50 to 350° C. of the glass substrate increases, the density of the glass substrate increases, and the later-described brittleness index of the glass substrate increases. The content thereof is preferably 1.5% or less, and more preferably 1% or less.

BaO: BaO can be contained because it has effects for decreasing the viscosity during melting of glass, and promoting melting. However, when its content exceeds 2% , there is a concern that the cell efficiency is lowered, and the average coefficient of thermal expansion within the range of 50 to 350° C. of the glass substrate increases, the density of the glass substrate increases, and the later-described brittleness index of the glass substrate increases. The content thereof is preferably 1.5% or less, and more preferably 1% or less.

ZrO₂: ZrO₂ can be contained because it has effects for decreasing the viscosity during melting of glass, and promoting melting. However, when its content exceeds 2.5%, there is a concern that the cell efficiency is lowered, and devitrification temperature is increased to easily cause the devitrification, resulting in difficulty of forming the sheet glass. The content thereof is preferably 1.5% or less, and more preferably 1% or less.

TiO₂: TiO₂ may be contained in an amount of up to 2.5% for the purposes of enhancing the melting properties, and the like. When its content exceeds 2.5%, there is a concern that the devitrification temperature is increased to easily cause the devitrification, resulting in difficulty of forming the glass sheet. The content thereof is preferably 1.5% or less and more preferably 1% or less.

MgO, CaO, SrO, and BaO are contained in an amount of 7.7% or more in total from the standpoints of decreasing the viscosity during melting of glass and promoting melting. However, when the total content exceeds 17%, there is a concern that the devitrification temperature increases and the formability is deteriorated. The total content is preferably 8% or more, more preferably 9% or more, and still more preferably 10% or more. Also, the total content is preferably 16% or less, more preferably 15% or less, and still more preferably 14% or less.

Na₂O: Na₂O is a component which contributes to an enhancement of the cell efficiency of the CIGS solar cell and is an essential component. Also, Na₂O has effects for decreasing the viscosity at a melting temperature of glass and making it easy to perform melting, and therefore, it is contained in an amount of from 5.3 to 10.9%. Na is diffused into the photoelectric conversion layer of the CIGS constituted on the glass substrate and enhances the cell efficiency; however, when its content is less than 5.3%, there is a concern that the diffusion of Na into the photoelectric conversion layer of the CIGS on the glass substrate is insufficient, and the cell efficiency is also insufficient. The content is preferably 6.5% or more, and more preferably 7.5% or more.

When the content of Na₂O exceeds 10.9%, the average coefficient of thermal expansion within the range of 50 to 350° C. tends to become large, and the glass transition temperature tends to be lowered. In addition, the chemical durability is deteriorated. The content thereof is preferably 10.5% or less.

K₂O: K₂O has the same effects as those in Na₂O, and therefore, it is contained in an amount of from 0 to 10%. However, when its content exceeds 10%, there is a concern that the cell efficiency is lowered, the glass transition temperature is lowered, and the average coefficient of thermal expansion within the range of 50 to 350° C. of the glass substrate becomes large. In the case where K₂O is contained, its content is preferably 2% or more, and more preferably 3% or more. The content thereof is preferably 8% or less, and more preferably 6% or less.

Na₂O and K₂O: For the purpose of sufficiently decreasing the viscosity at a melting temperature of glass and for the purpose of enhancing the cell efficiency of a CIGS solar cell, the total content of Na₂O and K₂O is from 10.4 to 16%. The total content is preferably 10.5% or more, and more preferably 11% or more. However, when the total content exceeds 16%, there is a concern that the glass transition temperature excessively decreases. The total content is preferably 15% or less and more preferably 14% or less.

Al₂O₃ and MgO: For the purpose of suppressing the increase of the devitrification temperature, a ratio of MgO/Al₂O₃ is set to 0.9 or less. When the ratio exceeds 0.9, there is a concern that the devitrification temperature increases. The ratio is preferably 0.85 or less and more preferably 0.8 or less. Also, the ratio is preferably 0.2 or more, more preferably 0.3 or more, still more preferably 0.4 or more, and especially preferably 0.5 or more.

Na₂O, K₂O, SrO, BaO, Al₂O₃, and ZrO₂: For the purpose of maintaining the glass transition temperature sufficiently high and further improving weather resistance, a value of the following formula (2) is set to 2.2 or less. From the results of experiments and try and error, the present inventors have found that, in the case where each of the above components satisfies the range of the present application and the value obtained from the following formula is 2.2 or less, the average coefficient of thermal expansion within the range of from 50 to 350° C. satisfies from 75×10⁻⁷ to 95×10⁻⁷/° C. and the brittleness index satisfies less than 7,000 m^{-1/2} while the glass transition temperature is maintained sufficiently high.

When the value exceeds 2.2, there is a concern that the glass transition temperature decreases or the weather resistance is deteriorated. Moreover, when the value becomes excessively low, the viscosity at a high temperature increases, resulting in difficulty of melting and forming, so that the value is preferably 1 or more and more preferably 1.5 or more.

The reason why a coefficient of 2 is multipled by the content of Na₂O is that Na₂O shows an effect of decreasing Tg higher than the case where other components show.

(2Na₂O+K₂O+SrO+BaO)/(Al₂O₃+ZrO₂) (2)

Na₂O, K₂O, and Al₂O₃: For the purpose of maintaining the cell efficiency high, a value of the following formula (3) is set to 0.9 or more. From the results of experiments and try and error, the present inventors have found that, in the case where each of the above components satisfies the range of the present application and the value obtained from the following formula is 0.9 or more, the cell efficiency can be maintained high.

{(Na₂O+K₂O/Al₂O₃}×(Na₂O/K₂O) (3)

When the value is less than 0.9, there is a concern that the diffusion of sodium ion from the glass substrate into the CIGS layer is not sufficient and the cell efficiency decreases. The value is preferably 0.95 or more and more preferably 1 or more. Moreover, the value exceeds 2, the contribution to the efficiency is almost even but when the value is excessively high, there is a concenrn that the glass transition temperature decreases or the weather resistance is deteriorated. Therefore, the value is preferably 10 or less, more preferably 7 or less, and still more preferably 6 or less.

The following will describe the above formula (3). With regard to the first member of the above formula (3), since alkali difusion is suppressed when the aluminum ion in glass is changed from tetracordination to hexacordination, it is preferred that the amount of Al₂O₃ is relatively small as compared with the amount of alkali in glass. Therefore, the value of “(Na₂O+K₂O)/Al₂O₃” as the first member is preferably large.

With regard to the cell efficiency, since Na is more effective than K, it is surmised that the value of the second member is preferably large. More preferably, the value of “Na₂O/K₂O” as the second member is 1 or more. The reason is that the alkali diffusion is easier when the amount of Na is relatively large as compared with the amount of K owing to a mixed alkali effect.

The glass substrate for a Cu—In—Ga—Se solar cell of the present invention preferably contains, in terms of mol % on the basis of the following oxides,

from 58 to 69% of SiO₂,

from 7 to 12% of Al₂O₃,

from 0 to 0.5% of B₂O₃,

from 4 to 9% of MgO,

from 0 to 4.5% of CaO,

from 0 to 1.5% of SrO,

from 0 to 1.5% of BaO,

from 0 to 1.5% of ZrO₂,

from 0 to 1.5% of TiO₂,

from 6.5 to 10.5% of Na₂O, and

from 2 to 8% of K₂O,

wherein MgO+CaO+SrO+BaO is from 9 to 15%,

Na₂O+K₂O is from 10.5 to 15%,

MgO/Al₂O₃ is from 0.2 to 0.85,

(2Na₂O+K₂O+SrO+BaO)/(Al₂O₃+ZrO₂) is from 1 to 2.2,

(Na₂O+K₂O)/Al₂O₃×(Na₂O/K₂O) is from 0.9 to 10, and

the glass substrate has the glass transition temperature of from 650 to 700° C., the average coefficient of thermal expansion within a range of from 50 to 350° C. of from 75×10⁻⁷ to 90×10⁻⁷/° C., the relationship between a temperature (T₄), at which a viscosity reaches 10⁴ dPa·s, and a devitrification temperature (T_{L}) of T₄−T_{L}≧−20° C., the density of 2.58 g/cm³ or less, and the brittleness index of less than 6,800 m^{1/2}.

Though the glass substrate for a CIGS solar cell of the present invention is essentially composed of the foregoing base composition, it may contain other components each in an amount of 1% or less and in an amount of 5% or less in total within the range where an object of the present invention is not impaired. For example, there may be the case where ZnO, Li₂O, WO₃, Nb₂O₅, V₂O₅, Bi₂O₃, MoO₃, TlO₂, P₂O₅, and the like may be contained for the purpose of improving the weather resistance, melting properties, devitrification, ultraviolet ray shielding, refractive index, and the like.

Also, for the purpose of improving the melting properties and fining property of glass, SO₃, F, Cl, and SnO₂ may be added into the base composition such that these materials are contained each in an amount of 1% or less and in an amount of 2% or less in total in the glass substrate.

Also, for the purpose of enhancing the chemical durability of glass substrate, Y₂O₃ and La₂O₃ may be contained in an amount of 2% or less in total in the glass substrate.

Also, for the purpose of adjusting the color tone of the glass substrate, colorants such as Fe₂O₃ may be contained in the glass substrate. A content of such colorants is preferably 1% or less in total.

Taking an environmental load into consideration, it is preferable that the glass substrate for a CIGS solar cell of the present invention does not substantially contain As₂O₃ and Sb₂O₃. Also, taking the stable achievement of float forming into consideration, it is preferable that the glass substrate does not substantially contain ZnO. However, the glass substrate for a CIGS solar cell of the present invention may be manufactured by forming by a fusion process without limitation to forming by the float process.

### <Manufacturing Method of Glass Substrate for CIGS Solar Cell of the Present Invention>

A manufacturing method of the glass substrate for a CIGS solar cell of the present invention will be described.

In the case of manufacturing the glass substrate for a CIGS solar cell of the present invention, similar to the case of manufacturing conventional glass substrates for a solar cell, a melting/fining step and a forming step are carried out. Since the glass substrate for a CIGS solar cell of the present invention is an alkali glass substrate containing an alkali metal oxide (Na₂O and K₂O), SO₃ can be effectively used as a refining agent, and a float process or a fusion process (down draw process) is suitable as the forming method.

In the manufacturing step of a glass substrate for a solar cell, it is preferable to adopt, as a method for forming a glass into a sheet form, a float process in which a glass substrate with a large area can be formed easily and stably with an increase in size of solar cells.

A preferred embodiment of the manufacturing method of the glass substrate for CIGS solar cell of the present invention will be described.

First of all, a molten glass obtained by melting raw materials is formed into a sheet form. For example, the raw materials are prepared so that the glass substrate to be obtained has a composition as mentioned above, and the raw materials are continuously thrown into a melting furnace, followed by heating at from 1,550 to 1,700° C. to obtain a molten glass. Then, this molten glass is formed into a glass sheet in a ribbon form by applying, for example, a float process.

Subsequently, the glass sheet in a ribbon form is taken out from the float forming furnace, followed by cooling to a room temperature state by cooling means, and cutting to obtain a glass substrate for a CIGS solar cell.

### <Use Applications of Glass Substrate for CIGS Solar Cell>

The glass substrate for a CIGS solar cell of the present invention is suitable as a glass substrate or cover glass for CIGS solar cell.

In the case of applying the glass substrate for a CIGS solar cell of the present invention to a glass substrate for a CIGS solar cell, a thickness of the glass substrate is preferably 3 mm or less, more preferably 2 mm or less, and still more preferably 1.5 mm or less. Also, a method for forming a photoelectric conversion layer of CIGS on the glass substrate is not particularly limited.

As specific methods thereof, examples thereof include a vapor deposition method in which the photoelectric conversion layer is formed by vapor deposition; a selenization method in which the photoelectric conversion layer is formed by forming a precursor film containing Cu, Ga, and In by a sputtering method and subsequently exposing the precursor film to an atmosphere containing hydrogen selenide under a high temperature; and the like. However, in the case of the vapor deposition method, selenium tends to vaporize again when the substrate temperature becomes high, so that the selenization method is preferred. When the glass substrate for a CIGS solar cell of the present invention is used, a heating temperature during the formation of the photoelectric conversion layer can be set to from 500 to 700° C., preferably from 550 to 700° C., more preferably from 580 to 700° C., and still more preferably from 600 to 700° C. Taking a deposition step at a CIGS solar cell manufacturer into consideration, the heating temperature is preferably 680° C. or lower and more preferably 650° C. or lower for the purpose of improving lifetime of a production line.

In the case of using the glass substrate for a CIGS solar cell of the present invention for only a glass substrate for a CIGS solar cell, a cover glass and the like are not particularly limited. As other examples of a composition of the cover glass, soda lime glass and the like are mentioned.

In the case of using the glass substrate for a CIGS solar cell of the present invention as a cover glass of a CIGS solar cell, a thickness of the cover glass is preferably 3 mm or less, more preferably 2 mm or less, and still more preferably 1.5 mm or less. Also, a method for assembling the cover glass in a glass substrate including a photoelectric conversion layer is not particularly limited. In the case of assembling upon heating using the glass substrate for a CIGS solar cell of the present invention, its heating temperature can be set to from 500 to 700° C. and preferably from 600 to 700° C.

When the glass substrate for a CIGS solar cell of the present invention is used for both a glass substrate and a cover glass for a CIGS solar cell, since the coefficient of thermal expansion within the range of from 50 to 350° C. is equal, thermal deformation or the like does not occur during assembling the solar cell, and thus the case is preferred.

### <CIGS Solar Cell in the Present Invention>

Next, the solar cell in the present invention will be described.

The solar cell in the present invention includes a glass substrate including a photoelectric conversion layer of Cu—In—Ga—Se and a cover glass formed above the glass substrate, and one or both of the glass substrate and the cover glass are the glass substrate for a Cu—In—Ga—Se solar cell of the present invention.

The solar cell of the present invention will be hereunder described in detail by reference to the accompanying drawings. It should not be construed that the present invention is limited to the accompanying drawings.

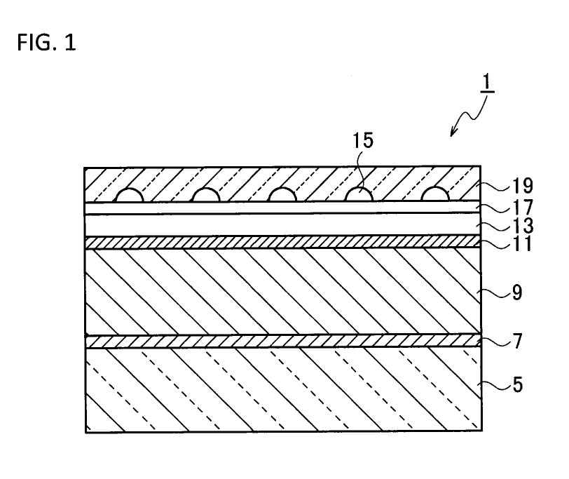

FIG. 1 is a cross-sectional view schematically showing an example of embodiments of the solar cell in the present invention.

In FIG. 1, the solar cell (CIGS solar cell) 1 in the present invention includes a glass substrate 5, a cover glass 19, and a CIGS layer 9 between the glass substrate 5 and the cover glass 19. The glass substrate 5 is preferably composed of the glass substrate for a CIGS solar cell of the present invention as described above. The solar cell 1 includes a back electrode layer of an Mo film that is a plus electrode 7 on the glass substrate 5, on which a photoelectric conversion layer that is the CIGS layer 9 is provided. As the composition of the CIGS layer, Cu(In₁₋ₓGaₓ)Se₂ can be exemplified. x represents a composition ratio of In and Ga and satisfies a relation of 0<x<1.

On the CIGS layer 9, a CdS (cadmium sulfide) layer, a ZnS (zinc sulfide) layer, a ZnO (zinc oxide) layer, a Zn(OH)₂ (zinc hydroxide) layer, or a mixed crystal layer thereof as a buffer layer 11 is provided. A transparent conductive film 13 of ZnO, ITO, Al-doped ZnO (AZO), or the like is provided through the buffer layer 11 and an extraction electrode such as an Al electrode (aluminum electrode) that is a minus electrode 15, and the like is further provided thereon. An antireflection film may be provided between these layers in a necessary place. In FIG. 1, an antireflection film 17 is provided between the transparent conductive film 13 and the minus electrode 15.

Also, the cover glass 19 may be provided on the minus electrode 15, and if necessary, a gap between the minus electrode and the cover glass is sealed with a resin or adhered with a transparent resin for adhesion. The glass substrate for a CIGS solar cell of the present invention may be used for the cover glass.

In the present invention, end parts of the photoelectric conversion layer or end parts of the solar cell may be sealed. Examples of a material for sealing include the same materials as those in the glass substrate for a CIGS solar cell of the present invention and the other glasses and resins.

It should not be construed that a thickness of each layer of the solar cell shown in the accompanying drawings is limited to that shown in the drawing.

The cell efficiency of the CIGS solar cell in the present invention is preferably 11.8% or more. When the efficiency is 11.8% or more, a sufficiently useful performance can be achieved as a solar cell. The efficiency is more preferably 12% or more and still more preferably 12.2% or more.

### EXAMPLES

The present invention will be hereunder described in more detail with reference to Examples and Manufacturing Examples, but it should not be construed that the present invention is limited to these Examples and Manufacturing Examples.

Examples of the present invention (Examples 1 to 30) and Comparative Examples (Examples 31 to 36) of the glass substrate for a CIGS solar cell of the present invention are shown. The numerical values in the parentheses in Tables 1 to 5 are calculated values.

Raw materials of respective components were made up so as to have a composition shown in Tables 1 to 5, a sulfate was added to the raw materials in an amount of 0.1 parts by mass as converted into SO₃ amount based on 100 parts by mass of the raw materials of the components for the glass substrate, followed by heating and melting at a temperature of 1,600° C. for 3 hours using a platinum crucible. In melting, a platinum stirrer was inserted, and stirring was performed for one hour, thereby homogenizing the glass. Subsequently, the molten glass was flown out and formed into a sheet form, followed by cooling to obtain a glass sheet.

With respect to the thus obtained glass sheet, an average coefficient of thermal expansion (unit: ×10⁻⁷/° C.) within the range of from 50 to 350° C., a glass transition temperature Tg (unit: ° C.), a temperature T₄ (unit: ° C.) at which the viscosity reached 10⁴ dPa·s, a devitrification temperature (T_{L}) (unit: ° C.), a density (unit: g/cm³), and a brittleness index (unit: m^{-1/2}) were measured and shown in Tables 1 to 5. Measuring methods of the respective physical properties are shown below.

In Examples, respective physical properties are measured for the glass sheet but are the same values in the glass sheet and the glass substrate. The glass substrate can be formed by subjecting the obtained glass sheet to processing and polishing.

(1) Tg: Tg is a value as measured using TMA and was determined in conformity with JIS R3103-3 (2001).

(2) Average coefficient of thermal expansion within the range of from 50 to 350° C.: The average coefficient of thermal expansion was measured using a differential thermal expansion meter (TMA) and determined in conformity with JIS R3102 (1995).

(3) Viscosity: The viscosity was measured using a rotary viscometer and a temperature T₂ (a reference temperature for melting properties) at which the viscosity η thereof reached 10² dPa·s, a temperature T₄ (a reference temperature for formability) at which the viscosity η thereof of glass reached 10⁴ dPa·s.

(4) Devitrification temperature (T_{L}): 5 g of a glass block cut from the glass sheet were put on a platinum dish and maintained at a predetermined temperature for 17 hours in an electric furnace. After the temperature maintenance, a maximum value of temperature at which a crystal was not precipitated on and inside the glass block was defined as the devitrification temperature.

(5) Density: About 20 g of a glass block containing no bubbles was measured by Archimedes method.

(6) Brittleness index: The brittleness index B is calculated using each of aforementioned various glass sheets as a glass substrate and using a size of the Vickers indentation marks formed on the glass substrate surface and the formula (1).

(7) Cell efficiency: A solar cell for evaluation was fabricated as shown below using the obtained glass sheet as a glass substrate for the solar cell and evaluation of the cell efficiency was performed using the solar cell. Results are shown in Tables 1 to 5.

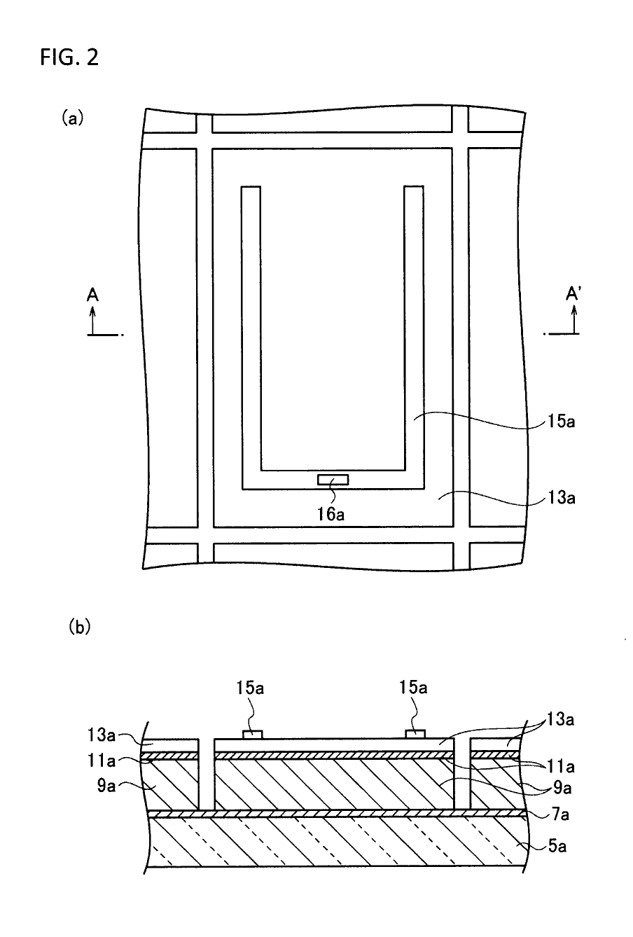

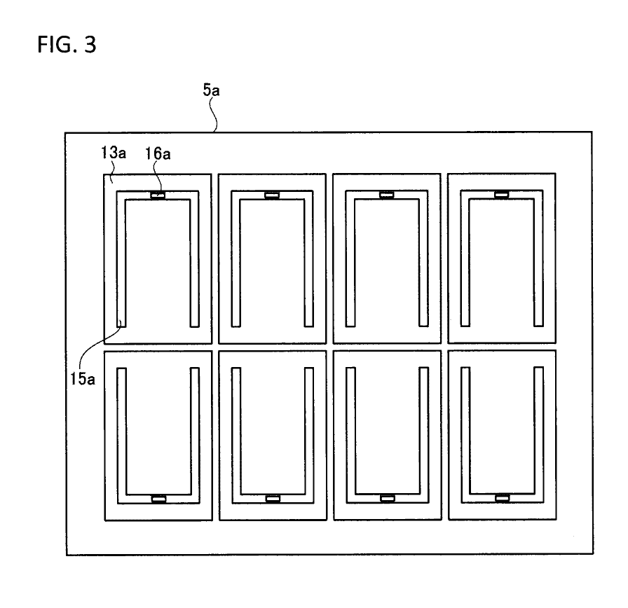

The fabrication of the solar cell for evaluation will be described below with reference to FIGS. 2 and 3 and reference numerals and signs thereof. The layer configuration of the solar cell for evaluation is almost the same as the layer configuration of the solar cell shown in FIG. 1 except that the cover glass 19 and antireflection film 17 of the solar cell in FIG. 1 are not included.

The obtained glass sheet was processed in a size of about 3 cm×3 cm and a thickness of 1.1 mm to obtain a glass substrate. A Mo film was formed as a plus electrode 7a on the glass substrate 5a by means of a sputtering apparatus. The film formation was carried out at room temperature and the Mo film having a thickness of 500 nm was obtained.

A CuGa alloy layer was formed on the plus electrode 7a (molybdenum film) by means of a sputtering apparatus using a CuGa alloy target and subsequently an In layer was formed using an In target, thereby forming a precursor film of In—CuGa. The film formation was carried out at room temperature. A thickness of each layer was adjusted so that a Cu/(Ga+In) ratio became 0.8 and a Ga/(Ga+In) ratio became 0.25 in the composition of the precursor film measured by fluorescent X-ray, thereby obtaining a precursor film having a thickness of 650 nm.

The precursor film was subjected to a heat treatment in a mixed atmosphere of argon and hydrogen selenide (using 5% by volume of hydrogen selenide relative to argon) using an RTA (Rapid Thermal Annealing) apparatus. First, as a first stage, the film was maintained at 250° C. for 30 minutes to react Cu, In, and Ga with Se. Thereafter, as a second stage, the film was further maintained at 520° C. for 60 minutes to allow CIGS crystal to grow, thereby obtaining a CIGS layer 9a. The thickness of the obtained CIGS layer 9a was 2 μm.

On the CIGS layer 9a, a CdS layer was formed as a buffer layer 11a by the CBD (Chemical Bath Deposition) process. Specifically, first, cadmium sulfate having a concentration of 0.01M, thiourea having a concentration of 1.0M, ammonia having a concentration of 15M, and pure water were mixed in a beaker. Then, the CIGS layer was dipped in the mixed solution and the beaker with the layer was placed in a constant temperature bath whose water temperature had been set to 70° C. beforehand, thereby forming a CdS layer with a thickness of from 50 to 80 nm.

Furthermore, a transparent conductive film 13a was formed on the CdS layer in a sputtering apparatus by the following method. First, a ZnO layer was formed using a ZnO target and then an AZO layer was formed using an AZO target (a ZnO target containing Al₂O₃ in an amount of 1.5 wt %). The film formation of each layer was carried out at room temperature and a two-layered transparent conductive film 13a having a thickness of 480 nm was obtained.

An aluminum film having a thickness of 1 μm was formed as a U-shaped minus electrode 15a on the AZO layer of the transparent conductive film 13a by EB deposition method (electrode length of the U-shape: (8 mm in length and 4 mm in width), electrode width: 0.5 mm).

Finally, the resultant was shaven from the transparent conductive film 13a side to the point of the CIGS layer 9a by means of a mechanical scribe, thereby forming a cell as shown in FIG. 2. FIG. 2(a) is a drawing in which one solar cell is viewed from the top face and FIG. 2(b) is a cross-sectional view at A-A′ in FIG. 2(a). One cell has a width of 0.6 cm and a length of 1 cm, and an area exclusive of the minus electrode 15a was 0.5 cm². As shown in FIG. 3, eight cells in total were obtained on one glass substrate 5a.

The CIGS solar cell for evaluation (the above glass substrate 5a for evaluation on which the eight cells were fabricated) was mounted on a solar simulator (YSS-T80A manufactured by Yamashita Denso Corporation); and a plus terminal (not shown) for the plus electrode 7a previously coated with an InGa solvent and a minus terminal 16a for the lower end of the U shape of the minus electrode 15a were respectively connected to a voltage generator. The temperature within the solar simulator was controlled constant at 25° C. by a temperature regulator. The solar cell was irradiated with a pseudo sun light and, after 60 seconds, the voltage was changed from −1 V to +1V at intervals of 0.015 V, thereby measuring a current value of each of the eight cells.

A cell efficiency was calculated from the current and voltage characteristics during the irradiation according to the formula (4). Among the eight cells, a value of the cell exhibiting the best efficiency is shown as a value of cell efficiency of each glass substrate in Tables 1 to 5. The illuminance of the light source used in the test was 0.1 W/cm².

Cell efficiency [%]=Voc[V]×Jsc[A/cm²]×FF(dimensionless)×100/(Illuminance of light source used for the test)[W/cm²] (4)

The cell efficiency is determined by multiplication of an open circuit voltage (Voc), a short-circuit current density (Jsc), and a fill factor (FF).

Here, the open circuit voltage (Voc) is an output when the terminal is opened; the short-circuit current (Isc) is a current when short-circuit is occurred. The short-circuit current density (Jsc) is one obtained by dividing Isc by an area of the cell exclusive of the minus electrode.

Also, a point at which a maximum output is given is called a maximum output point and a voltage at that point is called a maximum voltage value (Vmax) and a current at that point is called a maximum current value (Imax). A value obtained by dividing the product of the maximum voltage value (Vmax) and the maximum current value (Imax) by the product of the open circuit voltage (Voc) and the short-circuit current (Isc) is determined as the fill factor (FF). Using the above value, the cell efficiency was determined.

A residual amount of SO₃ in the glass substrate was from 100 to 500 ppm.

TABLE 1

| Composition [mol %] | Example 1 | Example 2 | Example 3 | Example 4 | Example 5 | Example 6 | Example 7 |
|---|---|---|---|---|---|---|---|
| SiO₂ | 65.5 | 64.0 | 62.5 | 62.0 | 62.5 | 62.0 | 62.0 |
| Al₂O₃ | 9.0 | 12.0 | 12.0 | 12.0 | 11.5 | 10.0 | 11.0 |
| MgO | 7.5 | 7.0 | 7.5 | 7.0 | 8.0 | 8.0 | 8.5 |
| CaO | 3.0 | 4.0 | 3.0 | 4.5 | 4.0 | 3.5 | 3.5 |
| SrO | 1.0 | 0.5 | 1.0 | 1.0 | 1.0 | 1.0 | 1.0 |
| BaO | 1.0 | 0 | 1.0 | 1.5 | 0.5 | 1.0 | 0.5 |
| Na₂O | 6.5 | 10.0 | 9.5 | 8.5 | 9.5 | 6.5 | 8.0 |
| K₂O | 5.0 | 2.0 | 2.5 | 3.0 | 2.0 | 6.5 | 4.5 |
| ZrO₂ | 1.5 | 0.5 | 1.0 | 0.5 | 1.0 | 1.5 | 1.0 |
| TiO₂ | 0 | 0 | 0 | 0 | 0 | 0 | 0 |
| B₂O₃ | 0 | 0 | 0 | 0 | 0 | 0 | 0 |
| MgO + CaO + SrO + BaO | 12.50 | 11.50 | 12.50 | 14.00 | 13.50 | 13.50 | 13.50 |
| Na₂O + K₂O | 11.50 | 12.00 | 12.00 | 11.50 | 11.50 | 13.00 | 12.50 |
| MgO/Al₂O₃ | 0.83 | 0.58 | 0.63 | 0.58 | 0.70 | 0.80 | 0.77 |
| (2Na₂O + K₂O + SrO + BaO)/ | 1.90 | 1.80 | 1.81 | 1.80 | 1.80 | 1.87 | 1.83 |
| (Al₂O₃ + ZrO₂) | | | | | | | |
| (Na₂O + K₂O)/Al₂O₃ × (Na₂O/K₂O) | 1.66 | 5.00 | 3.80 | 2.72 | 4.75 | 1.30 | 2.02 |
| Density (g/cm³) | (2.55) | 2.51 (2.50) | 2.57 (2.56) | (2.57) | 2.57 (2.55) | (2.57) | 2.56 (2.56) |
| Average coefficient of thermal | (77) | 79 (76) | 79 (77) | (78) | (76) | (84) | 85 (81) |
| expansion (×10⁻⁷/° C.) | | | | | | | |
| T_{g} (° C.) | (662) | 660 (660) | 665 (658) | (659) | (659) | (656) | 656 (657) |
| T₄ (° C.) | (1255) | (1254) | 1241 (1245) | (1228) | (1230) | (1227) | 1227 (1232) |
| T₂ (° C.) | (1695) | (1710) | 1651 (1684) | (1657) | (1665) | (1650) | 1634 (1665) |
| Devitrification temperature T_{L} (° C.) | 1232 | <1200 | 1230 | <1200 | <1175 | 1225 | 1225 |
| T₄ − T_{L} | 23 | >54 | 11 | >28 | >55 | 2 | 2 |
| Brittleness index (m^{-1/2}) | (6200) | 6050 | 6200 | (6500) | 6100 | (6350) | 6650 |
| Cell efficiency (%) | (14.5) | 14.7 | 14.4 | (15.1) | (14.7) | (13.3) | 15.3 |

TABLE 2

| Composition [mol %] | Example 8 | Example 9 | Example 10 | Example 11 | Example 12 | Example 13 | Example 14 |
|---|---|---|---|---|---|---|---|
| SiO₂ | 63.0 | 63.0 | 67.5 | 62.0 | 62.5 | 63.0 | 63.5 |
| Al₂O₃ | 11.0 | 10.0 | 8.5 | 10.5 | 11.0 | 12.0 | 12.0 |
| MgO | 8.0 | 7.0 | 5.0 | 7.5 | 8.5 | 7.0 | 7.0 |
| CaO | 3.0 | 3.5 | 3.5 | 3.5 | 4.0 | 4.5 | 4.0 |
| SrO | 0 | 0 | 1.0 | 1.0 | 1.0 | 1.0 | 0.0 |
| BaO | 0 | 0 | 1.0 | 1.0 | 0.5 | 1.0 | 0.0 |
| Na₂O | 7.5 | 7.5 | 5.5 | 6.0 | 7.0 | 8.5 | 10.0 |
| K₂O | 5.5 | 5.5 | 6.5 | 7.0 | 5.0 | 3.0 | 2.5 |
| ZrO₂ | 1.0 | 1.5 | 1.5 | 1.5 | 0.5 | 0 | 1.0 |
| TiO₂ | 1.0 | 2.0 | 0 | 0 | 0 | 0 | 0 |
| B₂O₃ | 0 | 0 | 0 | 0 | 0 | 0 | 0 |
| MgO + CaO + SrO + BaO | 11.00 | 10.50 | 10.50 | 13.00 | 14.00 | 13.50 | 11.00 |
| Na₂O + K₂O | 13.00 | 13.00 | 12.00 | 13.00 | 12.00 | 11.50 | 12.50 |
| MgO/Al₂O₃ | 0.73 | 0.70 | 0.59 | 0.71 | 0.77 | 0.58 | 0.58 |
| (2Na₂O + K₂O + SrO + BaO)/ | 1.71 | 1.78 | 1.95 | 1.75 | 1.78 | 1.83 | 1.73 |
| (Al₂O₃ + ZrO₂) | | | | | | | |
| (Na₂O + K₂O)/Al₂O₃ × (Na₂O/K₂O) | 1.61 | 1.77 | 1.19 | 1.06 | 1.53 | 2.72 | 4.17 |
| Density (g/cm³) | 2.51 (2.49) | 2.53 (2.52) | (2.54) | (2.57) | (2.54) | 2.55 (2.54) | (2.50) |
| Average coefficient of thermal | 83 (83) | 85 (83) | (78) | (84) | (81) | 81 (78) | (77) |
| expansion (×10⁻⁷/° C.) | | | | | | | |
| T_{g} (° C.) | 663 (658) | 654 (660) | (662) | (662) | (663) | 651 (660) | (662) |
| T₄ (° C.) | (1218) | 1231 (1206) | (1276) | (1243) | (1239) | (1239) | (1254) |
| T₂ (° C.) | (1658) | 1647 (1639) | (1728) | (1667) | (1675) | (1682) | (1704) |
| Devitrification temperature T_{L} (° C.) | 1245 | 1250 | 1275 | 1225 | <1200 | <1200 | <1250 |
| T₄ − T_{L} | −27 | −19 | 1 | 18 | >39 | >39 | >4 |
| Brittleness index (m^{-1/2}) | 5700 | 6500 | (6400) | (6450) | (6350) | 6500 | (6050) |
| Cell efficiency (%) | 12.7 | 14.2 | (12.9) | (12.5) | (14.1) | 15.2 | (14.8) |

TABLE 3

| | Example | Example | Example | Example | Example | Example | Example | Example |
|---|---|---|---|---|---|---|---|---|
| Composition [mol %] | 15 | 16 | 17 | 18 | 19 | 20 | 21 | 22 |
| SiO₂ | 68.00 | 67.50 | 63.50 | 63.00 | 66.25 | 66.25 | 62.00 | 60.75 |
| Al₂O₃ | 7.50 | 8.00 | 10.50 | 10.50 | 9.50 | 9.50 | 12.00 | 12.00 |
| MgO | 5.50 | 4.50 | 8.00 | 7.50 | 6.00 | 5.50 | 7.50 | 7.50 |
| CaO | 3.50 | 3.50 | 1.50 | 3.00 | 3.50 | 4.00 | 0.50 | 1.50 |
| SrO | 1.00 | 1.00 | 1.25 | 1.00 | 1.00 | 1.25 | 1.25 | 1.00 |
| BaO | 1.50 | 1.00 | 1.25 | 1.00 | 1.00 | 0.75 | 1.25 | 1.25 |
| Na₂O | 5.75 | 6.00 | 8.00 | 6.50 | 6.50 | 0.75 | 8.50 | 7.00 |
| K₂O | 5.50 | 6.50 | 4.50 | 5.50 | 5.25 | 5.00 | 5.50 | 7.50 |
| ZrO₂ | 1.75 | 2.00 | 1.50 | 1.50 | 1.00 | 1.00 | 1.50 | 1.50 |
| TiO₂ | 0 | 0 | 0 | 0 | 0 | 0 | 0 | 0 |
| B₂O₃ | 0 | 0 | 0 | 0.50 | 0 | 0 | 0 | 0 |
| MgO + CaO + SrO + BaO | 11.50 | 10.00 | 12.00 | 12.50 | 11.50 | 11.50 | 10.50 | 11.25 |
| Na₂O + K₂O | 11.25 | 12.50 | 12.50 | 12.00 | 11.75 | 11.75 | 14.00 | 14.50 |
| MgO/Al₂O₃ | 0.73 | 0.56 | 0.76 | 0.71 | 0.63 | 0.58 | 0.63 | 0.63 |
| (2Na₂O + K₂O + SrO + BaO)/ | 2.11 | 2.05 | 1.92 | 1.71 | 1.93 | 1.95 | 1.85 | 1.76 |
| (Al₂O₃ + ZrO₂) | | | | | | | | |
| (Na₂O + K₂O)/ | 1.57 | 1.44 | 2.12 | 1.35 | 1.53 | 1.67 | 1.80 | 1.13 |
| Al₂O₃ × (Na₂O/K₂O) | | | | | | | | |
| Density (g/cm³) | (2.56) | (2.55) | (2.57) | (2.55) | (2.54) | (2.54) | (2.56) | (2.57) |
| Average coefficient of thermal | (77) | (81) | (81) | (81) | (80) | (80) | (86) | (90) |
| expansion (×10⁻⁷/° C.) | | | | | | | | |
| T_{g} (° C.) | (656) | (656) | (657) | (660) | (659) | (657) | (656) | (657) |
| T₄ (° C.) | (1258) | (1256) | (1256) | (1231) | (1266) | (1261) | (1272) | (1263) |
| T₂ (° C.) | (1702) | (1714) | (1696) | (1653) | (1716) | (1712) | (1715) | (1695) |
| Devitrification temperature | <1263 | 1285 | 1285 | 1260 | 1295 | <1262 | 1300 | 1290 |
| T_{L} (° C.) | | | | | | | | |
| T₄ − T_{L} | >−5 | −29 | −29 | −29 | −29 | >−1 | −28 | −27 |
| Brittleness index (m^{-1/2}) | 6400 | 6500 | 6200 | 6300 | (6400) | (6400) | (6300) | (6450) |
| Cell efficiency (%) | 14.7 | 13.2 | 16.7 | 14.6 | (14.1) | 15.5 | (15.0) | (12.7) |

TABLE 4

| Composition | Example | Example | Example | Example | Example | Example | Example | Example |
|---|---|---|---|---|---|---|---|---|
| [mol %] | 23 | 24 | 25 | 26 | 27 | 28 | 29 | 30 |
| SiO₂ | 61.75 | 62.50 | 63.00 | 63.50 | 62.50 | 62.00 | 62.50 | 62.50 |
| Al₂O₃ | 11.50 | 12.00 | 11.50 | 11.00 | 12.00 | 12.00 | 12.00 | 12.00 |
| MgO | 8.00 | 7.50 | 7.50 | 7.50 | 7.00 | 7.00 | 7.00 | 7.00 |
| CaO | 2.50 | 3.00 | 3.00 | 3.50 | 3.00 | 3.00 | 3.00 | 3.00 |
| SrO | 1.00 | 1.00 | 1.00 | 1.00 | 1.50 | 1.25 | 1.00 | 1.00 |
| BaO | 1.25 | 0.50 | 0.50 | 1.00 | 0.50 | 1.25 | 0.50 | 0.50 |
| Na₂O | 7.25 | 10.00 | 9.00 | 8.00 | 9.50 | 8.50 | 9.50 | 9.50 |
| K₂O | 5.50 | 2.50 | 3.50 | 3.50 | 3.00 | 4.00 | 2.50 | 2.50 |
| ZrO₂ | 1.25 | 1.00 | 1.00 | 1.00 | 1.00 | 1.00 | 1.00 | 1.00 |
| TiO₂ | 0 | 0 | 0 | 0 | 0 | 0 | 1.00 | 0.75 |
| B₂O₃ | 0 | 0 | 0 | 0 | 0.00 | 0.00 | 0.00 | 0.25 |
| MgO + CaO + | 12.75 | 12.00 | 12.00 | 13.00 | 12.00 | 12.50 | 11.50 | 11.50 |
| SrO + BaO | | | | | | | | |
| Na₂O + K₂O | 12.75 | 12.50 | 12.50 | 11.50 | 12.50 | 12.50 | 12.00 | 12.00 |
| MgO/Al₂O₃ | 0.70 | 0.63 | 0.65 | 0.68 | 0.58 | 0.58 | 0.58 | 0.58 |
| (2Na₂O + | 1.75 | 1.85 | 1.84 | 1.79 | 1.85 | 1.81 | 1.77 | 1.77 |
| K₂O + | | | | | | | | |
| SrO + BaO)/ | | | | | | | | |
| (Al₂O₃ + ZrO₂) | | | | | | | | |
| (Na₂O + K₂O)/ | 1.46 | 4.17 | 2.80 | 2.39 | 3.30 | 2.21 | 3.80 | 3.80 |
| Al₂O₃ × | | | | | | | | |
| (Na₂O/ | | | | | | | | |
| K₂O) | | | | | | | | |
| Density | (2.57) | (2.54) | (2.54) | (2.56) | (2.55) | (2.57) | (2.54) | (2.54) |
| (g/cm³) | | | | | | | | |
| Average | (84) | (82) | (82) | (80) | (82) | (84) | (78) | (78) |
| coefficient of | | | | | | | | |
| thermal | | | | | | | | |
| expansion | | | | | | | | |
| (×10⁻⁷/° C.) | | | | | | | | |
| T_{g} (° C.) | (661) | (658) | (658) | (663) | (656) | (655) | (658) | (655) |
| T₄ (° C.) | (1252) | (1244) | (1249) | (1248) | (1248) | (1247) | (1216) | (1214) |
| T₂ (° C.) | (1682) | (1688) | (1694) | (1685) | (1692) | (1682) | (1643) | (1643) |
| Devitrification | 1280 | <1246 | <1250 | 1275 | <1278 | <1277 | <1240 | <1240 |
| temperature | | | | | | | | |
| T_{L} (° C.) | | | | | | | | |
| T₄ − T_{L} | −28 | >−2 | >−1 | −27 | >−30 | >−30 | >−24 | >−26 |
| Brittleness | (6350) | (6150) | (6200) | (6250) | (6050) | (6350) | (6150) | (6150) |
| index (m^{-1/2}) | | | | | | | | |
| Cell | (13.8) | 15.0 | 15.1 | (15.1) | (15.0) | (15.2) | (14.9) | (14.9) |
| efficiency (%) | | | | | | | | |

TABLE 5

| Composition [mol %] | Example 31 | Example 32 | Example 33 | Example 34 | Example 35 | Example 36 |
|---|---|---|---|---|---|---|
| SiO₂ | 61.0 | 62.0 | 63.0 | 67.0 | 64.5 | 66.5 |
| Al₂O₃ | 9.0 | 8.75 | 9.5 | 7.0 | 9.0 | 4.7 |
| MgO | 15.5 | 12.5 | 9.5 | 9.0 | 8.5 | 3.4 |
| CaO | 2.5 | 2.5 | 2.5 | 2.0 | 3.0 | 6.2 |
| SrO | 1.0 | 1.5 | 0 | 1.0 | 1.0 | 4.7 |
| BaO | 0 | 0.3 | 0 | 0.5 | 1.0 | 3.6 |
| Na₂O | 4.5 | 5.5 | 6.5 | 5.0 | 7.5 | 4.8 |
| K₂O | 6.5 | 6.0 | 7.0 | 6.5 | 3.5 | 4.4 |
| ZrO₂ | 0 | 1.0 | 2.0 | 2.0 | 2.0 | 1.7 |
| TiO₂ | 0 | 0 | 0 | 0 | 0 | 0 |
| B₂O₃ | 0 | 0 | 0 | 0 | 0 | 0 |
| MgO + CaO + SrO + BaO | 19.00 | 16.75 | 12.00 | 12.50 | 13.50 | 17.90 |
| Na₂O + K₂O | 11.00 | 11.50 | 13.50 | 11.50 | 11.00 | 9.20 |
| MgO/Al₂O₃ | 1.72 | 1.43 | 1.00 | 1.29 | 0.94 | 0.72 |
| (2Na₂O + K₂O + SrO + BaO)/ | 1.83 | 1.92 | 1.74 | 2.00 | 1.86 | 3.48 |
| (Al₂O₃ + ZrO₂) | | | | | | |
| (Na₂O + K₂O)/Al₂O₃ × (Na₂O/K₂O) | 0.85 | 1.20 | 1.32 | 1.26 | 2.62 | 2.14 |
| Density (g/cm³) | 2.52 | 2.56 | 2.53 | (2.54) | (2.57) | 2.77 |
| Average coefficient of thermal | 82 | 82 | 86 | (76) | (74) | 83 |
| expansion (×10⁻⁷/° C.) | | | | | | |
| T_{g} (° C.) | 664 | 655 | 667 | (663) | (661) | 620 |
| T₄ (° C.) | (1213) | (1218) | (1252) | (1264) | (1238) | 1136 |
| T₂ (° C.) | (1633) | (1640) | (1685) | (1706) | (1666) | 1537 |
| Devitrification temperature T_{L} (° C.) | >1263 | >1268 | >1302 | >1313 | >1275 | 1080 |
| T₄ − T_{L} | <−50 | <−50 | <−50 | <−50 | <−37 | 56 |
| Brittleness index (m^{-1/2}) | 5900 | 5900 | 5700 | (5900) | (5950) | 7000 |
| Cell efficiency (%) | 11.1 | 13.1 | 14.1 | (13.2) | (15.1) | (16.2) |

The brittleness index values of Examples 1 to 30 are less than 7,000 m^{-1/2}.

As is clear from Tables 1 to 4, in the glass substrates of Examples of the present invention (Examples 1 to 30), the glass transition temperature Tg is as high as 650° C. or higher, and the glass substrates have an average coefficient of thermal expansion within the range of from 50 to 350° C. of from 75×10⁻⁷ to 95×10⁷1° C., a brittleness index B of less than 7,000 m^{-1/2}, a density of 2.6 g/cm³ or less, and T₄−T_{L} of −30° C. or higher. Also, the cell efficiency is excellent.

The values in parentheses in Tables 1 to 5 are calculated values.

The brittleness index was calculated by performing multiple regression analysis with the composition and the found values based on the obtained found values and using a regression formula obtained therefrom. Taking measurement errors into consideration, it was calculated at intervals of 50.

A relation between the values obtained from the above formula (3) and the cell efficiency is proportional in the region where the values obtained from the above formula (3) was 2.2 or less, and when the values exceed 2.2, the cell efficiency becomes almost constant. Therefore, the cell efficiency was separately determined from the regression formula obtained by plotting the values of the above formula (3) and the cell efficiency with dividing the region into the region where the values of the above formula (3) was 2.2 or less and the region where the values of the above formula (3) exceeds 2.2.

Using the values P obtained from the above formula (3), the calculated values of the cell efficiency η was calculated using the following formula (5) in the case where P is 2.2 or less and was calculated using the following formula (6) in the case where P exceeds 2.2.

η=3.47×P+8.77 (5)

η=−0.20×P+15.62 (6)

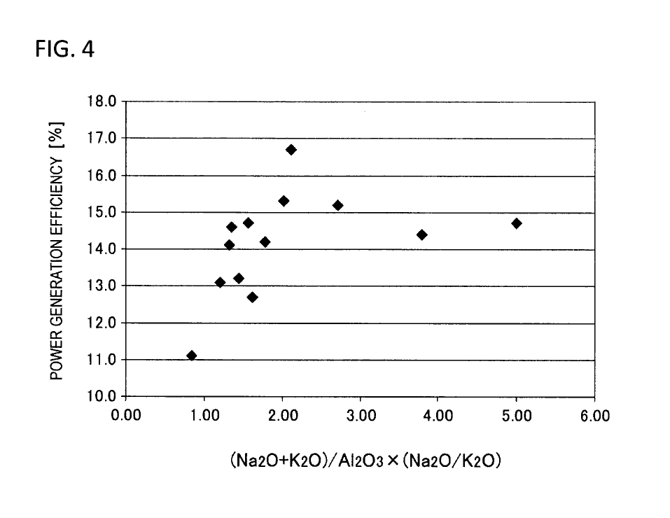

FIG. 4 shows a graph showing a relationship between (Na₂O+K₂O)/Al₂O₃×(Na₂O/K₂O) and the cell efficiency. As is clear from FIG. 4, it is revealed that the cell efficiency is excellent in the case where the value of (Na₂O+K₂O)/Al₂O₃×(Na₂O/K₂O) is 0.9 or more. From this result, it is predicted that Examples in which the values of (Na₂O+K₂O)/Al₂O₃×(Na₂O/K₂O) is 0.9 or more exhibit good cell efficiency.

Accordingly, since high cell efficiency, high glass transition temperature, a predetermined average coefficient of thermal expansion, high glass strength, low glass density, and prevention of devitrification during sheet glass formation can be all achieved, the CIGS photoelectric conversion layer is not peeled from the glass substrate with Mo film, the glass substrate is less prone to deform during assembling the solar cell (specifically, during assembling of the glass substrate including the photoelectric conversion layer of CIGS and the cover glass under heating) in the present invention, and the glass substrate has good strength, is light in weight, is not devitrified, and is more excellent in the cell efficiency.

On the other hand, as shown in Table 5, since the glass substrates of Comparative Examples (Examples 31 to 35) have T₄−T_{L} of lower than −30° C. and are prone to be devitrified, forming by a float process is difficult.

Moreover, Tg is low in Comparative Example (Example 36) and thus the glass substrate is prone to deform during film formation at 600° C. or higher, so that the manufacture of the cell may be hindered.

The glass substrate for a Cu—In—Ga—Se solar cell of the present invention is suitable as a glass substrate and cover glass for a CIGS solar cell, and also can be used as a substrate and cover glass for other solar cells.

### INDUSTRIAL APPLICABILITY

The glass substrate for a Cu—In—Ga—Se solar cell of the present invention can have properties of high cell efficiency, high glass transition temperature, a predetermined average coefficient of thermal expansion, high glass strength, low glass density, and prevention of devitrification during sheet glass formation with good balance. Thus, a solar cell exhibiting high cell efficiency can be provided by using the glass substrate for a CIGS solar cell of the present invention.

### DESCRIPTION OF REFERENCE NUMERALS AND SIGNS

1: Solar cell

5, 5a: Glass substrate

7, 7a: Plus electrode

9, 9a: CIGS layer

11, 11a: Buffer layer

13, 13a: Transparent conductive film

15, 15a: Minus electrode

16a: Minus terminal

17: Antireflection film

19: Cover glass

1. A glass substrate for a Cu—In—Ga—Se solar cell, containing, in terms of mol % on the basis of the following oxides,
from 55 to 70% of SiO₂,
from 6.5 to 12.6% of Al₂O₃,
from 0 to 1% of B₂O₃,
from 3 to 10% of MgO,
from 0 to 4.8% of CaO,
from 0 to 2% of SrO,
from 0 to 2% of BaO,
from 0 to 2.5% of ZrO₂,
from 0 to 2.5% of TiO₂,
from 5.3 to 10.9% of Na₂O, and
from 0 to 10% of K₂O,
wherein MgO+CaO+SrO+BaO is from 7.7 to 17%,
Na₂O+K₂O is from 10.4 to 16%,
MgO/Al₂O₃ is 0.9 or less,
(2Na₂O+K₂O+SrO+BaO)/(Al₂O₃+ZrO₂) is 2.2 or less,
(Na₂O+K₂O)/Al₂O₃×(Na₂O/K₂O) is 0.9 or more, and
the glass substrate has a glass transition temperature of from 650 to 750° C., an average coefficient of thermal expansion within a range of from 50 to 350° C. of from 75×10⁻⁷ to 95×10⁻⁷/° C., a relationship between a temperature (T₄), at which a viscosity reaches 10⁴ dPa·s, and a devitrification temperature (T_{L}) of T₄−T_{L}≧−30° C., a density of 2.6 g/cm³ or less, and a brittleness index of less than 7,000 m^{-1/2}.

2. The glass substrate for a Cu—In—Ga—Se solar cell according to claim 1, which contains, in terms of mol % on the basis of the following oxides,
from 58 to 69% of SiO₂,
from 7 to 12% of Al₂O₃,
from 0 to 0.5% of B₂O₃,
from 4 to 9% of MgO,
from 0 to 4.5% of CaO,
from 0 to 1.5% of SrO,
from 0 to 1.5% of BaO,
from 0 to 1.5% of ZrO₂,
from 0 to 1.5% of TiO₂,
from 6.5 to 10.5% of Na₂O, and
from 2 to 8% of K₂O,
wherein MgO+CaO+SrO+BaO is from 9 to 15%,
Na₂O+K₂O is from 10.5 to 15%,
MgO/Al₂O₃ is from 0.2 to 0.85,
(2Na₂O+K₂O+SrO+BaO)/(Al₂O₃+ZrO₂) is from 1 to 2.2,
(Na₂O+K₂O)/Al₂O₃×(Na₂O/K₂O) is from 0.9 to 10, and
the glass substrate has the glass transition temperature of from 650 to 700° C., the average coefficient of thermal expansion within a range of from 50 to 350° C. of from 75×10⁻⁷ to 90×10⁻⁷/° C., the relationship between a temperature (T₄), at which a viscosity reaches 10⁴ dPa·s, and a devitrification temperature (T_{L}) of T₄−T_{L}≧−20° C., the density of 2.58 g/cm³ or less, and the brittleness index of less than 6,800 m^{-1/2}.

3. A solar cell, comprising a glass substrate, a cover glass, and a photoelectric conversion layer of Cu—In—Ga—Se formed between the glass substrate and the cover glass,
wherein at least the glass substrate of the glass substrate and the cover glass is the glass substrate for a Cu—In—Ga—Se solar cell according to claim 1.

4. A solar cell, comprising a glass substrate, a cover glass, and a photoelectric conversion layer of Cu—In—Ga—Se formed between the glass substrate and the cover glass,
wherein at least the glass substrate of the glass substrate and the cover glass is the glass substrate for a Cu—In—Ga—Se solar cell according to claim 2.
